(19) United States
(12) Patent Application Publication
(10) Pub. No.: US 2003/0064307 A1
(43) Pub. Date: Apr. 3, 2003

(54) Process for forming latent image, process for detecting latent image, process and device for exposure, exposure apparatus, resist and substrate

(75) Inventors: Toru Nakamura, Kawasaki-shi (JP); Seitaro Ohno, Tokyo (JP)

Correspondence Address: OLIFF & BERRIDGE, PLC, P.O. BOX 19928, ALEXANDRIA, VA, 22320, US

(73) Assignee: Nikon Corporation, Chiyoda-ku (JP)

(21) Appl. No.: 10/287,632

(22) Filed: Nov. 5, 2002

Related U.S. Application Data
(63) Continuation of application No. 09/676,809, filed on Oct. 2, 2000, now abandoned.

(30) Foreign Application Priority Data
Oct. 5, 1999 (JP) PATENT 11-284459
Feb. 15, 2000 (JP) P 2000-037086
Aug. 1, 2000 (JP) P 2000-233396

(51) Int. Cl. G03C 5/00; G03B 27/00; G03F 9/00; G03C 1/76; G01B 11/00; G03C 1/494; G03C 1/492

(52) U.S. Cl. 430/22; 430/292; 430/30; 355/18; 356/400; 430/270.1

(57) ABSTRACT

It is an object to make it possible to easily carry out alignment of an exposure apparatus. A process for forming a latent image, which comprises irradiating a master plate having a pattern with exposure light and irradiating a substrate coated with a resist with the exposure light transmitted through said master plate or reflected on said master plate via a projection optical system, thereby forming the image of the pattern on the substrate, wherein the image of said pattern is formed on said substrate by making use of a change in color of a predetermined substance, included in said resist, that changes color upon irradiation with said exposure light.

### BACKGROUND OF THE INVENTION

1. Field of the Invention

The present invention relates to an exposure apparatus which can be used in the production of semiconductor devices and liquid crystal devices. In particular, the present invention relates to a process for detecting a latent image and to a process for forming the latent image, the processes being employed for evaluating the precision of the apparatus using the latent image.

2. Description of Related Art

As semiconductor devices become smaller, the requirements for the alignment accuracy of the exposure apparatus become increasingly demanding. Alignment of the exposure apparatus refers to the operation of matching the positions of a master plate (reticle, mask) and an exposed substrate (silicon wafer, for example) via the exposure apparatus, that requires it to reproduce the relative positions of the three members in the three-dimensional space with a high accuracy.

Alignment of the exposed substrate with the exposure apparatus is carried out according to observation with an alignment microscope mounted on the exposure apparatus. The alignment microscope has a function of irradiating an alignment mark, that has been formed on a wafer in advance, with light of a wavelength different from that of the exposure light, and to detect diffracted light or scattered light.

Methods of alignment include the TTL method wherein alignment of the exposed substrate that is loaded on a movable stage of the exposure apparatus is detected by means of a projection optical system, and the off-axis method wherein the exposed substrate is placed under the alignment microscope that is located at a position different from the projection optical system by moving the movable stage and alignment is detected in this state.

As semiconductor devices become smaller, the line width of the circuit patterns to be scribed by the photolithography process using the exposure apparatus become increasingly smaller. To scribe very fine patterns, it is effective to use light of a shorter wavelength in the exposure. Therefore, the wavelength of the exposure light of the exposure apparatus has been shifting from the g line (436 nm) to the i line (365 nm) and to KrF excimer laser light (248 nm), and an exposure apparatus has recently been developed that uses ArF excimer laser light (193 nm) of an even shorter wavelength.

As the wavelength of the exposure light becomes shorter as described above, it becomes difficult to carry out the alignment in the TTL method with a high accuracy. This is because correction of aberrations is carried out in the projection optical system based on the wavelength of the exposure light, and alignment light of wavelengths longer than that of the exposure light experiences significant aberration. In the past, when exposure light of relatively long wavelengths such as the g line was used, the difference in wavelength between the exposure light and the alignment light was small and alignment could be carried out with high accuracy by the TTL method. As exposure apparatuses have started to employ light sources of shorter wavelengths such as KrF excimer laser light in recent years as described previously, however, the TTL method has been deemed impractical, and an off-axis method has been employed in the alignment.

In the off-axis alignment method, the exposed substrate is first aligned with an alignment microscope that is located at a position different from the projection optical system. The exposed substrate is then moved over the distance (baseline) from the position of the alignment microscope that has been measured in advance to the projection optical system with reference to the coordinates of the position measured with an interferometer mounted on a stage that carries the exposed substrate. As a consequence, alignment by the off-axis method imposes demanding requirements to align the exposed substrate accurately with the alignment microscope, measure the stage position accurately with the interferometer and, further, to accurately measure the positional relationship of the alignment microscope and the projection optical system, that is to improve the accuracy of baseline measurement.

In the prior art, baseline measurement has been carried out by using a reference plate (fiducial mark) attached at a corner of the movable stage. The fiducial mark has an alignment mark for baseline measurement provided thereon, so that the baseline is measured from both the stage position when the alignment mark is detected with the alignment microscope and the stage position at the time of detection via the projection optical system.

However, baseline measurement using the fiducial mark has several problems. For example, an error is caused by changes in the relative positions of the fiducial mark and the interferometer optics due to thermal expansion and other reasons. Also because the fiducial mark is located at the corner of the stage, moving the mark to a position below the projection optical system or the alignment microscope causes the stage to move over almost the full stroke thereof. This may result in an error due to deformation of the exposure apparatus body and other reasons.

In order to avoid the problems described above, a method was proposed in which the exposed substrate is coated with a substance that allows it to obtain an image (latent image) only by irradiating it with the exposure light without carrying out a development process, the alignment mark provided on the master plate is transferred onto the exposed substrate only by irradiating it with the exposure light and the transferred mark is used as the alignment mark. That is, the alignment mark provided on the master plate (mask) is transferred via the projection optical system onto the exposed substrate as a latent image, then the stage is moved and the latent image is detected with the alignment microscope. The baseline is determined by measuring the travel of the stage by means of the interferometer mounted on the stage.

As a material that enables the formation of the latent image as described above, Japanese Unexamined Patent Application, First Publication No. Hei 6-50716 discloses a magneto-optical material and a photochromic material. Japanese Unexamined Patent Application, First Publication No. Hei 8-55788 discloses a technique using a substance whose refractive index changes when irradiated with light.

The method that uses an magneto-optical material as the latent image forming material has the problem that materials which allow stable recording with short-wavelength exposure lights that have recently been used are not available. Moreover, it is necessary to provide a specialized optical system in the exposure apparatus in order to carry out writing and reading functions, thus leading to increased size of the apparatus and an increase in the production cost.

Photochromic materials are divided into inorganic substances and organic substances. Among inorganic substances, photochromic glass that uses silver halide has been commercially utilized for adjustable transmissivity lenses of glasses. This is made by applying heat treatment so that fine particles of silver halide about several hundreds of angstrom in diameter precipitate in the glass medium. Since this requires a special process, there have been the problems that it is difficult to form the film on an exposed substrate and that the particles, which are a color source, and the presence of grain boundaries, make the substance unsuited to the formation of fine patterns.

While a number of organic photochromic materials are known, the wavelengths of the light used in writing for most of these substance are that of the i line or longer. Thus there has been the problem that stable marks cannot be recorded since molecular chains are broken before developing a color when light of a short wavelength such as KrF excimer laser light or ArF excimer laser light is used. Also a photochromic material has such the property that their color fades on exposure to heat, and consequently the formed marks change over time. Therefore, photochromic substances are not suited to the measurement of a baseline that requires high accuracy.

There are several substances whose refractive index changes when irradiated with light, but the magnitude of the change in the refractive index is generally small and it is difficult to read.

None of the materials described above is used in ordinary semiconductor production processes. Therefore, a special facility is required in order to form a latent image forming layer on the exposed substrate, leading to an increase in the production cost.

### BRIEF SUMMARY OF THE INVENTION

The present invention aims to solve the problems in forming latent images encountered in the prior art as described above. An object of the invention is to make it possible to easily form a latent image of a fine mark that is suited to alignment with a high accuracy even when irradiated with light of such a short wavelength that is used in exposure.

It also aims to provide a method which does not require that a special detecting system, other than the optical system of the prior art, be added for the purpose of writing and reading the mark. Further, it aims to provide a method which does not require the introduction of special equipment for forming a latent image forming layer on the exposed substrate.

Thus, an object of the present invention is to provide a process and a material for forming the latent image having a high practical value, and achieve baseline measurement of high accuracy at low cost.

The present inventors have studied many materials for forming a latent image in order to solve the problems described above. However, special materials are all expensive and are difficult to apply uniformly over the exposed substrate, and are therefore not suited to practical use.

In the course of their research, the present inventors found that an image appears without a development process, when a photoresist used in current lithography processes is applied to a silicon wafer under certain conditions and exposed to light under certain conditions.

More surprisingly, when the latent image was used to form an alignment mark which was then observed with the alignment microscope of the exposure apparatus, a signal of sufficient strength could be obtained and it was found that the latent image mark could be detected without making any modification to the alignment microscope of the prior art.

It was also found that the reproducibility of repeated detection (measurement) of the mark is of similar level to that using a fiducial mark.

The present inventors, upon careful examination of latent images, found that the resist in a portion irradiated with light contracted more than the resist in a portion that was not irradiated with light. It was also found that a resist that does not show latent images contracts to a lesser extent.

Close examination of the contraction revealed that alignment with a high accuracy can be achieved when the ratio of contraction of the resist upon irradiation of light is not less than 3%.

Measurement of the spectral reflectivity of the resist showed a difference in phase of the interference fringe pattern between a portion that was irradiated with light and a portion not irradiated. This is because the interference conditions change as the thickness of the resist changes.

The present inventors also have made a resist from a substance which changes color upon irradiation by light and formed an alignment mark by making use of the change in color. It was found that such a method of position detection is excellent as the change in reflectivity in the portion where the alignment mark is recorded is detected with the alignment microscope.

While various substances can be used for a resist that changes color upon irradiation with light, the inventors found that it is particularly effective to make use of a change in color that occurs when a substance which produces an acidic or basic substance upon irradiation with light acts on another coexisting substance, namely a substance that changes color in reaction to the acidic or basic substance.

Thus, the first aspect of the present invention is “a process for forming a latent image, which comprises irradiating a master plate having a pattern with exposure light and irradiating a substrate coated with a resist with the exposure light transmitted through said master plate or reflected on said master plate via a projection optical system, thereby forming the image of the pattern on the substrate, wherein the image of said pattern is formed on said substrate by making use of a change in color of a predetermined substance, included in said resist, that changes color according to the irradiation with said exposure light”.

The second aspect of the present invention is “a process for forming a latent image according to the first aspect, wherein said resist includes a specific substance that produces an acidic or basic substance when irradiated with the light; and said predetermined substance changes color in reaction to the acidic or basic substance produced by the specific substance”.

The third aspect of the present invention is “a process for forming a latent image according to the first aspect, wherein said resist is a chemical sensitization type resist that includes said predetermined substance added thereto”.

The fourth aspect of the present invention is “a process for forming a latent image, which comprises irradiating a master plate having a pattern with exposure light and irradiating a substrate coated with a resist with the exposure light transmitted through said master plate or reflected on said master plate via a projection optical system, thereby forming the image of said pattern on said substrate, wherein said substrate is irradiated with said exposure light of such a wavelength that changes the thickness of said resist film by at least 3%, thereby forming the image of said pattern on said substrate”.

The fifth aspect of the present invention is “a process for detecting a latent image, which comprises irradiating said substrate having the latent image of said pattern being formed thereon with detection light of a wavelength different from that of said exposure light, using the process for forming a latent image of any one of first to fourth aspects, and detecting light generated by the latent image when irradiated with the detection light, thereby detecting said latent image”.

The sixth aspect of the present invention is “an exposure process, which comprises determining positional information of said latent image detected using the process for detecting a latent image of the fifth process, and carrying out alignment of said substrate or measurement of the alignment accuracy according to the positional information of said latent image”.

The seventh aspect of the present invention is “a device produced by employing the exposure process of the sixth aspect”.

The eighth aspect of the present invention is “an exposure apparatus for forming an image of a pattern on a substrate by irradiating a master plate having the pattern with exposure light and irradiating the substrate coated with the resist with the exposure light transmitted through the master plate or reflected on the master plate via a projection optical system, comprising: a detector which detects a latent image, which has been formed on said substrate by making use of a change in the color of a predetermined substance, that changes color when irradiated with said exposure light and is included in a resist, by irradiating detection light of a wavelength different from that of the exposure light; and an alignment device which carries out alignment of said substrate according to the result of the detection by said detector”.

The ninth aspect of the present invention is “an exposure apparatus of the eighth aspect, wherein the resist includes a specific substance that produces an acidic or basic substance when irradiated with the light and the predetermined substance changes color in reaction to the acidic or basic substance produced by the specific substance”.

The tenth aspect of the present invention is “an exposure apparatus of the eighth or ninth aspect, wherein the resist is a chemical sensitization type resist that includes the predetermined substance added thereto”.

The eleventh aspect of the present invention is “an exposure apparatus for forming an image of a pattern on a substrate by irradiating a master plate having the pattern with light and irradiating the substrate coated with the resist with the light transmitted through said master plate or reflected on said master plate via a projection optical system, comprising: a detector which detects a latent image, which is formed on said substrate by irradiating said substrate with exposure light of a wavelength that changes the thickness of said resist by at least 3%, by using detection light of a wavelength different from that of said exposure light; and an alignment device which carries out alignment of said substrate according to the result of detection by said detector”.

The twelfth aspect of the present invention is “a resist comprising a specific substance that produces an acidic or basic substance when irradiated with light of a predetermined wavelength and a predetermined substance that changes color in reaction to the acidic or basic substance produced by the specific substance”.

The thirteenth aspect of the present invention is “a resist according to the twelfth aspect, wherein the resist is a chemical sensitization type resist that includes the predetermined substance added thereto”.

The fourteenth aspect of the present invention is “a resist that reduces its thickness thereof by at least 3% when irradiated with light having a predetermined wavelength”.

The fifteenth aspect of the present invention is “a resist according to the fourteenth aspect, wherein the resist is a chemical sensitization type resist”.

The sixteenth aspect of the present invention is “a substrate that is coated with the resist of any one of the twelfth to fifteenth aspects and forms a latent image through a change in the resist by an irradiation with the light of the predetermined wavelength”.

According to the present invention, it is possible to form an alignment mark in the form of a latent image by the exposure apparatus and read the alignment mark without using a special material or a special apparatus. Since it is not necessary to add a special material or a special apparatus, the measurement process using the latent image according to the present invention can be readily introduced into an existing semiconductor production line.

Also because the baseline measurement of the present invention can be carried out in a short period of time, variations in the baseline can be corrected more frequently than in the case of using the method of the prior art, thereby making it possible to achieve a high alignment accuracy and produce semiconductor devices of high reliability with a high non-defective ratio.

The measurement process using the latent image according to the present invention can also be used in many applications, as well as baseline measurement, such as the evaluation of the optical performance of a projection optical system, evaluation of the feeding accuracy of a stage, detection of the amount of rotation of a master plate such as reticle and detection of the projection magnitude error.

Moreover, the measurement process using the latent image according to the present invention can also be used in the assembly or adjustment of an exposure apparatus, making it possible to greatly reduce the time taken in the assembly and adjustment and reduce the consumption of chemicals such as developer solution, thereby providing assembly and adjustment processes that involve less environmental pollution.

### BRIEF DESCRIPTION OF THE DRAWINGS

FIG. 1 shows the layout of an exposure apparatus in a portion around a stage thereof.

FIG. 2 shows the layout of a projection optical system, an alignment optical system and the stage of the exposure apparatus.

FIG. 3 is a flow chart showing an example of a semiconductor device production process.

FIG. 4 is a plan view showing a reticle on which a reticle pattern is formed.

FIG. 5 is a plan view showing a substrate on which an alignment mark is formed.

FIG. 6 is an enlarged view showing a part of FIG. 2 for the explanation of the method of baseline measurement.

### DETAILED DESCRIPTION OF THE INVENTION

The present invention employs a photoresist, that is used in semiconductor processes, as a latent image forming material. In the present invention, the term “latent image” refers collectively to marks that are formed by exposure only, without a development process. Thus the resist used as the latent image forming material is required to undergo some change in its properties when irradiated with light. There are many properties that can be changed by light, such as magnetic properties, refractive index, film thickness, light scattering characteristics, light absorbing characteristics and light reflecting characteristics. While latent image forming methods that utilize these properties may be conceived, the present inventors decided that methods that utilize the changes in light absorbing characteristics and light reflecting characteristics would be preferable. This is because alignment of an exposure apparatus employs a method in which the alignment mark is illuminated and detected by means of a signal in the form of diffracted light or scattered light from the mark. That is, use of a property that can be detected directly and reliably by means of light, in detecting the latent image, makes it possible to carry out alignment by measuring the latent image without making a substantial modification of the alignment optical system of an existing exposure apparatus.

Embodiment 1

First, as the first embodiment of the latent image forming process according to the present invention, a latent image forming process will be described below wherein the image of a pattern formed on a master plate is transferred onto a substrate by irradiating the substrate with exposure light of a wavelength that changes the thickness of a resist film by at least 3%.

In a semiconductor process, either exposed portions or unexposed portions of a photoresist are normally removed by developing after exposure, thereby transferring the pattern from the master plate. According to the present invention, on the contrary, a photoresist that contracts significantly when irradiated with light is used so that only the portion irradiated with light contracts thereby forming a pattern. The contracted portion can be recognized by unaided eye because of the change in the interference color.

In order to detect the latent image with high accuracy by means of an alignment microscope, the shrinkage ratio of the resist upon irradiation with light is preferably 3% or higher. When the shrinkage ratio is less than 3%, irradiation with light causes less change in the film thickness, which makes it difficult to detect with the alignment microscope.

While there is no limitation to the thickness of the photoresist film that is formed according to this embodiment, the resist film used in the semiconductor process tends to become thinner as the semiconductor device becomes smaller. Therefore, it is preferable to set the thickness of the photoresist film used for forming the latent image in this embodiment equal to that of the ordinary process, which results in less work required for control. Normally, the thickness is 1 μm or less.

The photoresist is usually applied by a spin coating process to an exposed substrate such as a silicon wafer or a glass substrate, and is exposed after being pre-baked. The photoresist can be used without pre-baking in this embodiment, although it is desirable to apply pre-baking, considering fact that a solvent evaporated during exposure may be a source of contamination of the exposure apparatus. The baking temperature is normally in a range from 40° C. to 25° C., and the duration of baking is from 10 seconds up to one hour. When the baking temperature is lower than 40° C., the solvent does not fully evaporate and this results in insufficient effect of baking. When the baking temperature is higher than 250° C., the resist layer becomes too hard, thus resulting in a lower shrinkage ratio and lower alignment accuracy for the latent image.

Similarly, a shorter period of baking leads to insufficient effect of baking. A longer period of baking leads not only to a lower alignment accuracy but also to a lower productivity.

There is no limitation to the photoresist used in the present invention as long as the photoresist contracts when irradiated with light.

For example, a resist comprising a novolak resin and a dissolution inhibitor such as diazonaphthoquinone, or a so-called chemical sensitizer type resist comprising a resin such as polyvinyl phenol, polyacrylate or a novolak resin individually or in a mixture thereof and a photo acid generating agent may be used. However, the present invention is not limited to these materials.

The present inventors found that a latent image can be formed by using a number of commercial resist products, and that the chemical sensitizer type resist has a particularly high shrinkage ratio and is most suitable for forming a latent image.

The light source of the exposure apparatus is used in the irradiation with light for forming the latent image in the present invention. As a result, light (exposure light) of various wavelengths can be used when forming the-latent image, such as the g line (436 nm), the i line (365 nm), KrF excimer laser light (248 nm), ArF excimer laser light (193 nm), F2 laser light (157 nm) and X rays.

The integrated light intensity irradiated when forming the latent image may be similar to that used in the manufacture of the semiconductor device, although a slightly higher intensity leads to clearer contrast of the latent image and results in higher alignment accuracy. When a KrF excimer laser is used in forming the latent image, for example, an integrated light intensity of about 10 to 1000 mJ/cm² is preferable.

Light of any wavelength may be used in detecting the latent image as long as the photoresist does not contract when irradiated with the light of that particular wavelength. However, use of the alignment optical system of the exposure apparatus of the prior art in detecting the latent image eliminates the need to prepare a new optical system for forming and detecting the latent image, and is therefore very advantageous in terms of cost. As light having wavelengths in and near a region from 400 nm to 800 nm, He—Ne laser light (633 nm) or the like is used in the alignment systems of the prior art, it is preferable to use such light.

The latent image is detected by photoelectric detection of light which is diffracted or scattered by the surface unevenness of the latent image by means of the alignment microscope. At this time, the position of the alignment microscope where the mark is observed can be determined by reading the stage position with an interferometer when the signal from the latent image is detected by the alignment microscope. A line segment connecting the stage position where the latent image was exposed to light by the projection optical system and the position where the mark is observed with the alignment microscope that is measured by the process described above becomes the baseline.

In this embodiment, as described above, the latent image is formed on the exposed substrate such as a silicon wafer or a glass substrate and is then detected with the alignment microscope. Thus the position of the stage whereon the exposed substrate is fixed is exactly the same as that where the semiconductor device is exposed to light, and therefore there are no problems such as deflection and errors in rotation, caused by differences in the stage position that are encountered when measuring the baseline using the fiducial mark.

Baseline measurement according to this embodiment does not require a special substrate (such as a test wafer) to be used, and uses the exposed substrate (process wafer) that is used in ordinary semiconductor processes with a resist applied thereon. Consequently, errors arising from problems of parallelism and flatness of the substrate in the baseline measurement can be eliminated, thus making it possible to carry out measurement with high accuracy.

Also, because the photoresist used in the ordinary process for producing a semiconductor device can used in the baseline measurement using the latent image of this embodiment, no special provisions are necessary. Moreover, the baseline measurement can be carried out in a very short period of time, and therefore the measurement can be made frequently during the process for producing a semiconductor device.

As semiconductor devices become increasingly smaller, it has become more important to control the errors originating in the equipment such as slight deformations of the exposure apparatus in use. According to the process of the present invention, it is possible to carry out baseline measurement frequently and to take the measured values as the equipment parameters, thereby achieving a stable alignment accuracy without increasing the cost.

The measurement method using the latent image of the present invention can be applied to many other measurements as well as the baseline measurement. For example, a plurality of marks are provided at each of the center and the four corners of a master plate, and are exposed to light at the same time thereby forming latent images on the exposed substrate. Then the factor of magnification and the aberration characteristic of the projection optical system can be determined by measuring the relative positions of the marks that are obtained as latent images.

When exposure is repeated while moving the stage by a predetermined step for every shot with reference to the reading of the interferometer, the accuracy of the interferometer or the stage can be evaluated by measuring the space between the latent images and the variability thereof.

The exposure apparatus is usually provided with a movable blind to shield a part of the master plate from light. According to the present invention, the normal functioning of the blind can be checked by moving the blind to a predetermined position, carrying out exposure and checking the size and inclination of the exposed area that is obtained as the latent image.

The measurement method using the latent image of the present invention can be applied, not only to the case in which the exposure apparatus is used in the semiconductor process, but also to the assembly and adjustment processes of the exposure apparatus. In the assembly and adjustment processes of the exposure apparatuses of the prior art, in order to check the accuracy of the exposure apparatus, it was the common practice to apply exposure and development processes to a wafer that is coated with a photoresist and measure the resist image thus obtained visually under a microscope or by means of a special inspection apparatus, or to carry out measurement with the alignment optical system by placing the wafer on the exposure apparatus again. According to the present invention, however, development of the photoresist is not necessary, and measurement can be started immediately upon forming the latent image. This makes it possible to greatly reduce the time taken in the processes of assembly and adjustment of the exposure apparatus. Moreover, since the exposed substrate may remain on the stage without being removed therefrom throughout the processes from exposure to measurement, the occurrence of errors due to development and removal or mounting of the substrate can be prevented, thereby making it possible to easily carry out adjustment with higher accuracy.

Now the process for detecting a latent image, the process for exposure and the exposure apparatus according to the first embodiment of the process for forming a latent image described above will be described with reference to the accompanying drawings. Since the construction of the exposure apparatus is well known through disclosure by, for example, Japanese Patent Application, First Publication No. Hei 5-21314, Japanese Patent Application, First Publication No. Hei 5-217835 and Japanese Patent Application, First Publication No. Hei 10-141915, the construction will be described only in outline, and a detailed description of the inner structure will be omitted.

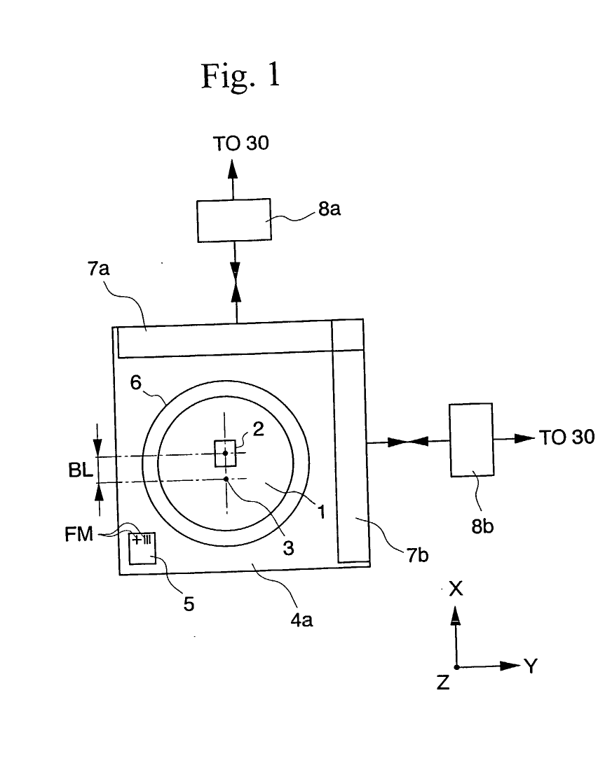

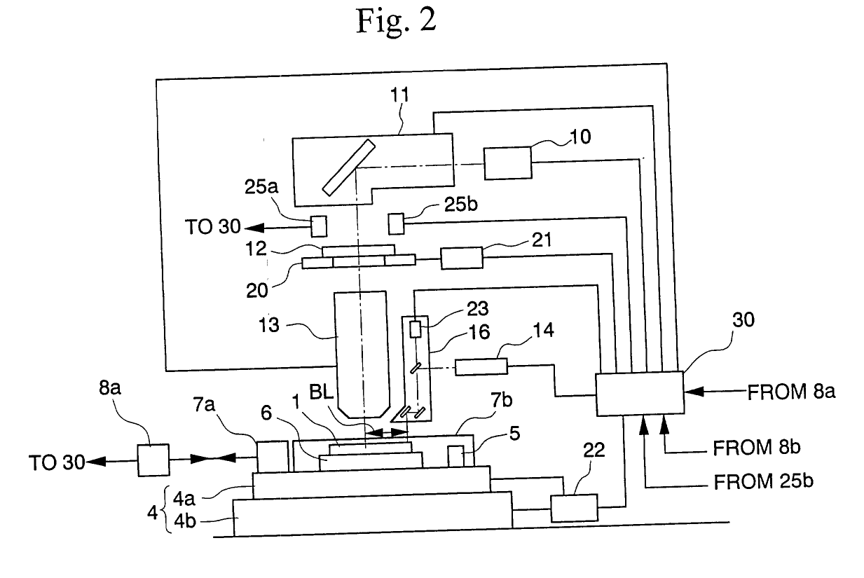

FIG. 1 is a schematic diagram of the exposure apparatus in a portion around the stage thereof viewed from above, and FIG. 2 is a schematic side view of the exposure apparatus. The exposure apparatus used in this embodiment is a scan type exposure apparatus of a step and scan system (scanning stepper) wherein the reticle pattern is transferred onto a substrate while moving the reticle and the substrate in synchronization with respect to the exposure light.

The exposure light generated by an exposure light source 10 (KrF excimer laser) is irradiated onto a mask or a reticle (master plate) 12 via an illuminating optical system 11. The exposure light source is not limited to that described above, and may be an ArF excimer laser, a mercury lamp using the g line (436 nm) or i line (365 nm), an F₂ laser (157 nm) or a source of X rays or charged particle rays such as an electron beam.

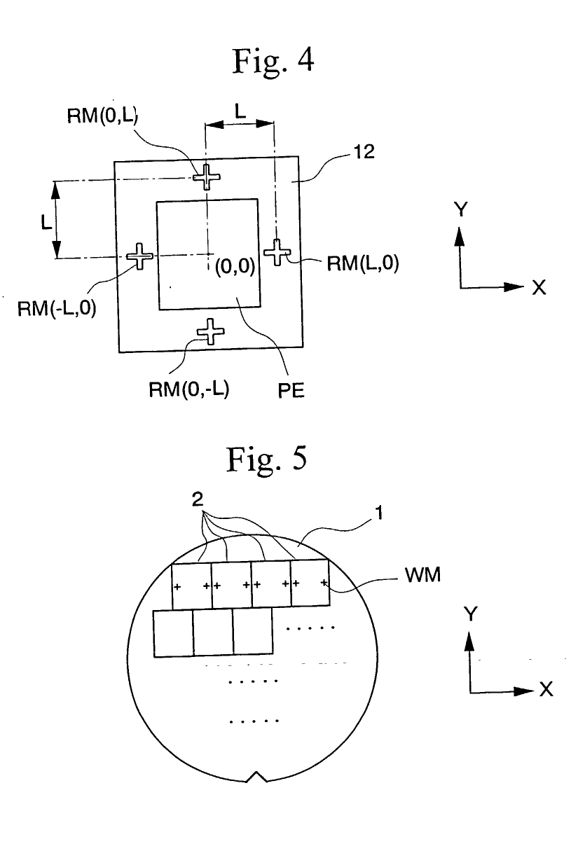

As shown in FIG. 4, the reticle 12 has a reticle pattern (circuit pattern that makes a part of a device pattern region PE and reticle alignment mark RM provided on the periphery of the device pattern region PE) being formed thereon. When the reticle 12 is irradiated with the exposure light, an image of the reticle pattern is projected and transferred onto an exposed substrate 1 (for example, a silicon wafer) via a projection optical system 13. The reticle alignment marks RM are formed at a distance of predetermined design value L from the center of the reticle as shown in FIG. 4.

The projection optical system 13 projects the reticle pattern by reducing the size thereof by a predetermined factor of a (for example, a=¼). The projection optical system 13 is optimized for the aberration of the exposure light.

The reticle 12 is held on a reticle stage 20 by means of, for example, vacuum sucking, electrostatic chucking or an electromagnet, and the reticle stage 20 has a construction that allows it to move or make minute rotations in two-dimensional space (the X-Y plane) by means of a reticle stage drive system 21 provided with a motor. During scanning exposure, the reticle stage 20 is driven by the stage drive system 21 to move in the scan direction (Y direction).

The substrate 1 is placed on a substrate stage 4. The substrate stage 4 includes an XY stage 4b that is moved in two-dimensional space (the X-Y plane) by a substrate stage drive system 22 provided with a motor (not shown) and a Zθ stage 4a that is placed on the XY stage 4b and is driven by the substrate stage drive system 22 to move in the Z direction and make minute rotation about the Z axis. During scanning exposure, the XY stage 4b to be described later of the substrate stage 4 is driven by the stage drive system 22 to move in the scanning direction (in −Y direction when the reticle stage 20 moves in +Y direction).

The Zθ stage 4a carries a substrate holder 6 that holds the substrate 1 by vacuum sucking, electrostatic chucking or other methods, movable mirrors 7a, 7b consisting of planar mirrors fastened onto the ends of the stage 4a, and a reference mark plate 5 consisting of a transparent material having a low expansion coefficient such as quartz fixed on the stage 4a, mounted thereon. Formed on the surface of the reference mark plate 5 are various reference marks (fiducial marks) FM that are used in alignment and are formed by vapor deposition of chromium or the like. Although the reference mark FM is not used during measurement of the baseline to be described later, the reference mark FM may be used for other than the measurement of the baseline (for example, for the measurement and adjustment of aberration of the substrate alignment system or adjustment of a focal point detection system (not shown)), and accordingly the reference mark plate 5 is provided on the exposure apparatus.

The position of the substrate 1 placed on the substrate stage 4 (Zθ stage 4a) in the XY plane is measured with laser interference systems 7, 8. The position of the substrate 1 in the X direction is measured by projecting a ranging light beam from the interferometer 8a onto the movable mirror 7a and receiving the reflected light with a detector that is installed in the interferometer 8a, thereby to determine the position according to the received light. The position of the substrate 1 in the Y direction is measured by projecting a ranging light beam from the interferometer 8b onto the movable mirror 7b and receiving the reflected light with a detector installed in the interferometer 8b, thereby to determine the position according to the result of receiving the light. Measurement data by these interferometers 8 are sent to a main control system 30.

Installed between the illumination optical system 11 and the reticle stage 20 are reticle alignment systems (RA systems) 25a, 25b of the image capturing system for observing the reticle alignment marks RM formed on the reticle 12. The RA systems 25 are used mainly for detecting positional information of the reticle alignment marks RM which are used during the reticle alignment operation where the center of the reticle 12 is aligned with the center of the projection optical system 13. The RA systems 25 are also capable of observing the reticle alignment marks RM and the alignment mark WM (FIG. 5) formed on the substrate 1. An image signal from an image pickup device (not shown) installed inside the RA systems 25 is supplied to the main control system 30.

Since the RA systems 25 use the exposure light in detection, the marks are detected after adjusting the intensity of the alignment light to a level below that for proper light exposure as the photoresist applied on the substrate 1 receives a predetermined amount of light, when observing the latent image formed on the substrate 1. When the total light exposure (integrated light exposure) of the alignment light intensity irradiated on the substrate 1 (photoresist) when detecting the mark is controlled to be less than the proper light exposure described above, the same mark can be detected (irradiated with light) any number of times.

A substrate alignment system 16 of off-axis type is provided on the side of the projection optical system. The substrate alignment system 16 includes an alignment light source 14 as a second light source that generates alignment light (detection light) of a wavelength different from that of the exposure light, an illuminating optical system (not shown) that guides the alignment light onto the substrate and a receiving optical system (not shown) that guides the light generated from the alignment mark provided on the substrate by irradiating with alignment light onto a photoelectric element 23. The substrate alignment system 16 illuminates the alignment mark WM formed on the substrate 1 with the alignment light and receives light, that is diffracted or scattered by the alignment mark WM under illumination, with the photoelectric element 23. A photoelectric signal from the photoelectric element 23 is sent to the main control system 30.

For the alignment light source, a He—Ne laser is used when the alignment system 16 is based on LIA (Laser Interferometric Alignment) or LSA (Laser Step Alignment) method, or a halogen lamp is used when the alignment system 16 is based on FIA (Field Image Alignment) method. These alignment methods (LIA, LSA, FIA) are well known through the publications described previously, and will not be described here.

The main control system 30 is electrically connected to various components to control the alignment according to the signal sent from the interferometers 8a, 8b and the photoelectric element 23 and the imaging signal from the RA system 25, control the exposure light source 10 and the alignment light source 14, control the illuminating optical system 11 (for example, changing the illuminating system NA and changing diaphragms that have various apertures and are installed in the illuminating optical system thereby to switch between oblique illumination and normal illumination), change the imaging characteristic of the projection optical system and/or NA (by driving some of the projection lenses) and control the reticle stage drive system 21 and the substrate stage drive system 22.

Described below are the method of exposure to transfer the image of the reticle pattern formed on the reticle 12 onto the wafer 1 and the baseline measurement method using the exposure apparatus that has the construction described above.

First, the center of the reticle 12 that is held on the reticle stage 20 is aligned with the optical axis of the projection optical system 13 by controlling the driving of the reticle stage drive system 21 according to the result of monitoring with the RA system 25.

Then a shutter (not shown) of the exposure apparatus is opened for a predetermined period of time, thereby illuminating the reticle 12 that has been positioned as described above, with the exposure light emitted by the exposure light source 10 via the illuminating optical system 11. The substrate 1 is exposed to the illumination with incident energy of 90 mJ/cm². The image of the reticle alignment mark RM formed on the reticle 12 is formed, via the projection optical system 13, in an exposure are 2 on the substrate 1 that is coated with a latent image forming material. This causes a latent image mark WM (FIG. 5) to be formed on the substrate 1.

For the latent image forming material provided on the substrate 1, a commercialized chemical sensitizer type resist specific for KrF was used. The chemical sensitizer type resist specific for KrF was applied to the substrate 1 with a rotational speed of 4000 rpm and duration of rotation of 15 seconds, followed by baking at a temperature of 90° C. for 30 minutes. Measurement of the thickness of the baked resist film with a contact type film thickness meter showed that the thickness was 5600 Å. After exposure of the substrate 1, the thickness of the resist in the portion where the latent image was formed measured 5000 Å.

The projection optical system 13 has a fixed mirror (not shown) provided on the side in a lower portion thereof. The interferometers 8 (8a, 8b) measure the position of the substrate stage 4 in the X direction and the Y direction relative to the projection optical system 13 by causing the light rays reflected on the fixed mirror and on the movable mirrors 7a, 7b to interfere with each other.

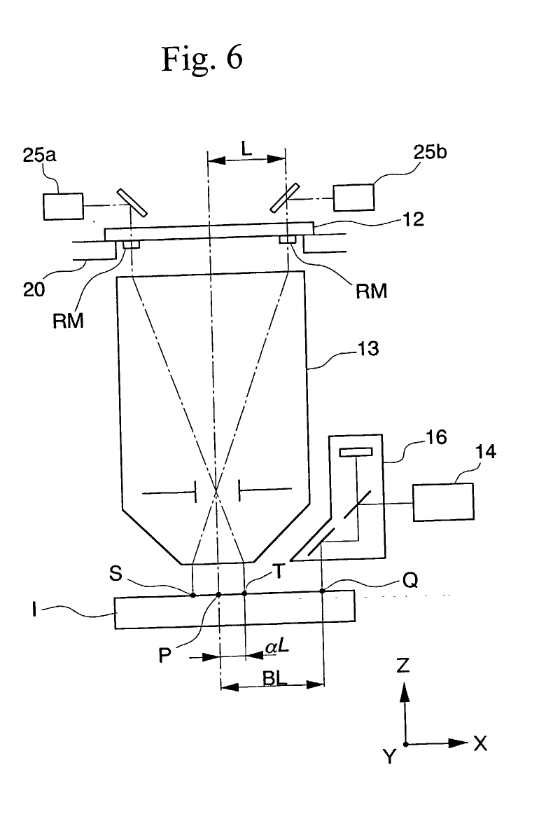

The baseline may be measured by either of the two methods that will be described below with reference to FIG. 6. FIG. 6 shows a part of FIG. 2 for the explanation of the method of baseline measurement.

In the first method, the position P of the substrate stage 4 when the latent image mark WM is formed on the substrate 1 (during exposure) (position of the optical axis of the projection optical system 13 or center position of the reticle 12 that has been aligned with the optical axis) is measured with the interferometers 8. The coordinates of the position P of the substrate stage 4 at this time are denoted as (X1, Y1).

Then the substrate stage 4 (XY stage 4b) is driven to move the latent image mark WM to a position Q below the substrate alignment system 16, in order to observe the latent image mark WM formed on the substrate (for example, the latent image mark WM formed at position T) with the substrate alignment system 16. The coordinates (X2, Y2) of the position Q at the time when the latent image mark WM are observed with the substrate alignment system 16 are measured with the interferometers 8.

The baseline BL represents the distance between the position P and the position Q as shown in FIG. 6. As described previously, the distance between the center of the reticle 12 and the reticle alignment mark RM in the X direction is determined (L) by design. Thus the distance between the center (optical axis center) P on the substrate 1 and the latent image mark WM forming positions S, T in the X direction is aL (a is the magnification factor of projection). Consequently, the coordinates of the position T are (X1+aL, Y1).

Thus the values of the baseline BL (BLX and BLY) are given as follows.

$$\begin{matrix}BLX = X1 + aL - X2 \\ BLY = Y1 - Y2\end{matrix}$$

The baseline is determined by the first method as described above.

Now the second method to determine the baseline will be described below. While the baseline is determined by using the coordinates of the substrate stage 4 measured during exposure in the first method, the baseline BL is determined by the second method according to the result of measurement of the latent image mark RM by means of the RA system 25 after the latent image mark RM is formed on the substrate 1.

First, the latent image mark RM formed at the position T on the substrate 1 is observed by using the RA system 25a, and the coordinates (XT, YT) at this time are measured with the interferometer 8. Based on the results of these measurements and the condition that the optical axis center is located at the middle of position S and position T, the coordinates (X1, Y1) of the optical axis center P are given as ((XT+XS)/2, (YT+YS)/2).

The method for measuring the coordinates (X2, Y2) of the position Q at the time when the latent image mark WM is observed with the substrate alignment system 16 for the latent image mark WM formed on the substrate (for example, the latent image mark WM formed at position T) is similar to the first method described above. What is measured with the substrate alignment system 16 is the latent image mark WM at the position T, not the center position of the reticle pattern. Giving consideration to this fact similarly to the first method, the values of the baseline BL (BLX and BLY) are given as follows.

$$\begin{matrix}BLX = X1 - X2 + aL = ( XT + XS ) / 2 - X2 + aL \\ BLY = Y1 - Y2 = ( YT + YS ) / 2 - X2\end{matrix}$$

The baseline is determined by the second method as described above.

The baseline BL measured as described above is used to align the exposure area 2 (shot region) of the substrate 1 with the exposure position in the exposure apparatus, and the device is produced through a process of transferring the image of the reticle pattern onto the exposure area 2 by using the exposure light described above.

Embodiment 2

Now the second embodiment of the latent image forming method according to the present invention will be described below, which is a method of forming the image of a pattern formed on a master plate on the substrate through a change in the color of a predetermined substance, included in the resist that changes color according to irradiation with the exposure light.

For the substances that change color when irradiated with light, a group of substances generally referred to as photochromic compounds are known. Photochromic compounds change color when irradiated with light and return to their original color in a dark place, and are roughly classified into inorganic substances and organic substances. Examples of inorganic substances include silver halide and tungsten oxide. Examples of organic substances include substances such as viologen, spiropyran, spirooxazine, diaryl ether and fulgide.

These photochromic compounds can be used as the resist of the present invention. However, many of the photochromic compounds experience breakage of their molecular chains before developing a color when irradiated with ultraviolet rays of a short wavelength and/or are likely to experience deterioration. Even after once developing a color, the state is not steadily maintained after the irradiation with light stops, and their color gradually fades due to heat, or the colored state changes in reaction to the light used in reading the marks, in many of the materials. In order to use a latent image for alignment of higher accuracy that will be required in the future, the latent image, once formed, must be more stable.

The present inventors found that a more stable latent image can be obtained by combining a substance that produces an acidic substance or a basic substance when irradiated with light, (hereafter referred to as a specific substance), instead of a material that directly changes color when irradiated with light, and a substance that changes color in reaction to the acidic substance or the basic substance (hereafter referred to as a predetermined substance). When combining the specific substance and the predetermined substance, since the acidic substance or the basic substance produced by the irradiation of light remains stable after the irradiation with light stops, the color change caused in reaction thereto is also maintained steadily. The color changes are not affected by the light illuminated for reading the mark.

In the description that follows, the specific substances which produce acidic substances when irradiated with light will be referred to as a photo acid generating agents and those which produce basic substances when irradiated with light will be referred to as a photo base generating agents.

In the present invention, the photo acid generating agent is not specifically limited as far as it generates an acid by irradiation with light having the exposure wavelength. Specific examples of the photo acid generator include, but are not limited to, diaryl iodonium salt, triaryl sulfonium salt, diarylmonoalkyl sulfonium salt, monoaryldialkyl sulfonium salt, triaryl selenonium salt, tetraaryl phosphonium salt, aryl diazonium salt, aromatic diazonium salt, aromatic sulfonium salt, aromatic iodonium salt, aromatic selenonium salt and aromatic phosphonium salt, that are represented by R⁴₂I⁺X⁻, R⁴₃S⁺X⁻, R⁴₂R⁵S⁺X⁻, R⁴R⁵₂S⁺X⁻, R⁴₃Se⁺X⁻, R⁴₄P⁺X⁻, R⁴N²⁺X⁻, R⁵₂I⁺X⁻, R⁵₃S⁺X⁻, R⁵₂R⁶S⁺X⁻, R⁵R⁶₂S⁺X⁻, R⁵₃Se⁺X⁻, R⁵₄P⁺X⁻ and R⁵N²⁺X⁻ (wherein R⁴ represents an aryl group; R⁵ represents an alkyl group; X⁻ represents an anion such as AsF⁶⁻, PF⁶⁻, BF⁴⁻, HSO⁴⁻, ClO⁴⁻, Cl⁻, CF₃SO³⁻ or B(C₆F₅)⁴⁻).

Examples of the photo base generating agent that produces a basic substance by irradiation with light include, but are not limited to, cobalt amine complex, trimethylbenzhydrylammonium iodide, O-acyloxime, carbamic acid derivative and formaldehyde derivative.

Examples of the substance (predetermined substance), that reacts with an acidic or basic substance to cause color change, include substances known as a pH indicator. Specific examples thereof include m-cresol purple, thymol blue, bromophenol blue, bromocresol green, chlorophenol red, bromophenol red, bromocresol purple, bromothymol blue, phenol red, cresol red, cresolphthalein, phenolphthalein, methyl orange and methyl red.

To form a thin film which simultaneously contains the photo acid generating agent, photo base generating material and pH indicator, a substrate to be subjected to light exposure may be coated with a solution prepared by dissolving or dispersing them in a polymer solution. The usable polymers are not specifically limited, but examples thereof include methyl polymethacrylate, polyacrylic acid, polyvinyl alcohol and polyvinyl butyral.

A simple method of simultaneously incorporating a photo acid generating agent and a pH indicator is to add the pH indicator to a commercially available chemical sensitizer type resist. Since the chemical sensitizer type resist includes a photo acid generating agent, when the pH indicator that changes the color thereof in response to acidity is added to the chemical sensitizer type resist, irradiation with light produces an acid which in turn changes the color of the pH indicator. The photo acid generating agent of the chemical sensitizer type resist is designed to have sensitivity to exposure light of the exposure apparatus, with wettability and viscosity optimized so that a uniform film can be formed over a silicon wafer by the spin coating process. Thus this method has the advantage that a practically useful material for forming a latent image can be prepared easily.

In this embodiment, there is no limitation to the thickness of the resist film to be formed, similarly to the first embodiment, and the thickness is set to, for example, 1 μm or less. Pre-baking of the resist can be omitted similarly to the first embodiment and, if pre-baking is applied, it is carried out at a predetermined temperature for a predetermined duration.

The light source of the exposure apparatus is used for forming the latent image, and light of various wavelengths may be used such as the g line (436 nm), the i line (365 nm), the light of a KrF excimer laser (248 nm), the light of an ArF excimer laser (193 nm), the light of a F₂ laser (157 nm) or X rays.

The integrated light intensity irradiated for forming the latent image may be similar to that of the exposure conditions used in the manufacture of semiconductor devices, or may be slightly higher. When a higher cumulative light energy is applied, a higher contrast of the latent image (alignment mark) is obtained and the alignment accuracy is improved. When a KrF excimer laser is used in forming the latent image, for example, an integrated light intensity of about 10 to 1000 mJ/cm² is preferable.

The latent image (alignment mark) can be detected efficiently by using the alignment optical system of the exposure apparatus of the prior art that employs light of wavelength in a range from 400 nm to 800 nm or light (633 nm) from a He—Ne laser, similarly to the first embodiment.

When using detection light of a wavelength of 400 nm to 600 nm as detection light from the alignment system, it is preferable to use, as a predetermined substance, a substance wherein the peak of light absorption induced by an acidic or basic substance is in a range from 400 nm to 600 nm because detection can be carried out with good accuracy. The predetermined substance includes, for example, m-cresol purple, bromophenol blue, bromocresol green, bromocresol purple or bromothymol blue.

Similarly, a preferable predetermined substance when using detection light of a wavelength of 400 nm to 600 nm is a substance wherein a peak of light absorption induced by an acidic or basic substance is in a range from 400 nm to 600 nm. The predetermined substance includes, for example, thymol blue, chlorophenol red, phenol red, cresol red, cresolphthalein, phenolphthalein, methyl orange or methyl red.

When using exposure light of a wavelength of 300 nm or less (for example, KrF excimer laser light, ArF excimer light, etc.) as exposure light for formation of a latent image, it is preferable to use, as a specific substance (photo acid generating agent, photo base generating agent), a substance having a light absorption spectrum of 300 nm or less because a stable reaction is carried out. The specific substance includes, for example, diaryl iodonium salt, triaryl sulfonium salt, diarylmonoalkyl sulfonium salt, monoaryldialkyl sulfonium salt, aromatic iodonium salt or cobalt amine complex. When using KrF excimer laser light, a particularly preferable specific substance is a substance having a light absorption spectrum at about 248 nm and examples thereof include carbamic acid derivative and formaldehyde derivative.

Similarly, when using exposure light having a wavelength of 400 nm or less (for example, light from an ArF excimer laser, a KrF excimer laser and the i line), a preferable specific substance is a substance wherein the wavelength range of the light absorption spectrum extends to near 400 nm. In this case, specific substance includes aromatic sulfonium salt.

The latent image is detected by photoelectric detection of light which is reflected on the alignment mark, that has changed color upon irradiation with light, by means of the alignment microscope. At this time, the position of the alignment microscope can be determined by reading the stage position with the interferometer when the signal from the latent image is detected by the alignment microscope. A line segment connecting the stage position where the latent image was exposed to light by the projection optical system and the position of the alignment microscope that is measured by the method described above becomes the baseline.

In this embodiment, as described above, effects similar to those of the first embodiment can be achieved, in that a fine alignment mark suitable for alignment with high accuracy can be easily formed as a latent image, also by making use of a change in the color of the predetermined substance that changes color upon irradiation with the exposure light.

Now the latent image detection method, the exposure method and the exposure apparatus according to the second embodiment of the latent image forming method described above will be described with reference to FIG. 1 and FIG. 2. Component parts identical equivalent to those of the first embodiment described previously will be denoted with identical reference numerals and descriptions thereof will be simplified or omitted.

When the reticle 12 having the alignment mark RM formed thereon is irradiated with the exposure light, the image is formed by the projection lens system 13 in the exposure area 2 on the silicon wafer 1 held on the wafer holder 6.

The He—Ne laser 14 is used for the alignment light source, similarly to the first embodiment, so that the alignment mark WM provided on the wafer is illuminated by the alignment optical system (not shown) installed in the alignment system 16 with the light diffracted or scattered being detected.

As the resist to be coated on the silicon wafer 1, a solution prepared by adding 40 parts by weight of methyl polymethacrylate (polymer, binder), 2 parts by weight of ADEKA OPTOMER SP170 and 0.01 parts by weight of bromophenol blue (pH indicator) to 20 parts by weight of methylene chloride as the solvent, followed by sufficient stirring was used.

The silicon wafer 1 was spin-coated with this resist and then baked at 100° C. for two minutes. The film thickness of the resist after baking was measured by using a contact type film thickness measuring device. It was found to be 1 μm.

With the silicon wafer 1 placed and fixed on the wafer holder 6 of the exposure apparatus, the XY stage 4 was moved so that the center of the silicon wafer 1 is located in the exposure area 2. (The coordinates of the stage at this time are denoted as (X1, Y1).) Then a shutter (not shown) of the exposure apparatus is opened for a predetermined period of time, thereby forming a latent image by irradiating with the exposure light of energy 100 mJ/cm².

After moving the XY stage 4b so that the latent image comes near the center of the alignment microscope 16, the alignment mark formed on the silicon wafer 1 in the form of the latent image was irradiated with the detection light thereby to detect the mark (the coordinates at this time are denoted as (X2, Y2)).

The baseline is measured by a method similar to the method of the first embodiment.

According to the first method, the values of the baseline BL (BLX and BLY) are given as follows.

$$\begin{matrix}BLX = X1 + aL - X2 \\ BLY = Y1 - Y2\end{matrix}$$

According to the second method, the values of the baseline BL (BLX and BLY) are given as follows.

$$\begin{matrix}BLX = X1 - X2 + aL = ( XT + XS ) / 2 - X2 + aL \\ BLY = Y1 - Y2 = ( YT + YS ) / 2 - X2\end{matrix}$$

The baseline BL measured as described above is used to align the exposure area 2 (shot region) of the substrate 1 with the exposure position in the exposure apparatus, and the device is produced through a process of transferring the image of the reticle pattern onto the exposure area 2 by using the exposure light described above.

The resist applied to the silicon wafer 1 was prepared from 100 parts by weight of a commercially available chemical sensitizer type resist and 1 part by weight of a 0.1% methanol solution of methyl orange (pH indicator). The silicon wafer coated with this resist by a spin coating process was baked at 110° C. for two minutes. The baked resist film after baking measured 0.8 μm in thickness. Then the baseline was determined by exposure and measurement of the latent image.

In both of the embodiments described above, the formation of a stable latent image and detection of the latent image were achieved.

The substrate used in the present invention is not limited to a semiconductor wafer used in the manufacture of a semiconductor device, and may be a glass plate used in a liquid crystal display devices or a ceramic wafer used for a thin film magnetic head.

The exposure apparatus is not limited to the scan type exposure apparatus (scanning stepper) and may be a step and repeat type exposure apparatus (stepper) wherein the reticle pattern is exposed while the reticle and the substrate are kept stationary, and the substrate is moved step by step.

The type of exposure apparatus is not limited to that used in the production of the semiconductor described above, and may also be an exposure apparatus used in liquid crystal display devices or the exposure-apparatus used for the production of thin film magnetic heads, image pickup devices (CCD) and reticles.

The projection optical system may operate, not only in reducing projections, but also in isometric or expanding projections.

The projection optical system employs quartz or fluorite that transmits deep ultraviolet rays as the window material when deep ultraviolet light emitted by an excimer laser is used, or an optical system based on reflective-refractive operation or refractive operation when an F₂ laser or X rays are used (the reticle should also be of the reflective type). When electron beams are used, an electron optical system consisting of electron lenses and deflectors may be used. Of course the path of the electron beam is pumped to a vacuum.

When a linear motor is used for the reticle stage and/or the substrate (wafer) stage, either an air-levitation type using air bearings or a magnetic levitation type using Lorentz force or reactance may be used. The mask stage and the substrate stage may be of the guided or guideless types.

When a planar motor is used for driving the stage, either one of a magnet unit (permanent magnet) and an armature unit is attached to the stage while the other is attached to the base.

The reactive force generated by the movement of the substrate stage may be received by the floor (ground) mechanically by means of frame members as described in Japanese Patent Application, First Publication No. Hei 8-166475. The present invention may also be applied to an exposure apparatus having such a configuration.

The reactive force generated by the movement of the reticle stage may be received by the floor (ground) mechanically by means of frame members as described in Japanese Patent Application, First Publication No. Hei 8-330224. The present invention may also be applied to an exposure apparatus having such a configuration.

As described above, the exposure apparatus according to the embodiment of the present application is produced by assembling various subsystems that include the components described in the claims of the present application, so that the predetermined mechanical accuracy, electrical accuracy and optical accuracy can be maintained. In order to ensure such accuracy, adjustments of the optical systems to achieve the optical accuracy, adjustments of the mechanical systems to achieve the mechanical accuracy and adjustments of the electrical systems to achieve the electrical accuracy are carried out before and after the assembly. The process of assembling various subsystems into the exposure apparatus include mechanical connection, wiring and interconnections of electrical circuits, and piping and connection of pneumatic circuits. It goes without saying that assembly of the subsystems precedes the process of assembling various subsystems into the exposure apparatus. When the process of assembling various subsystems into the exposure apparatus has been completed, overall adjustment is carried out to ensure the accuracy of the exposure apparatus as a whole. The exposure apparatus is produced preferably in a clean room where the temperature and cleanliness are controlled.

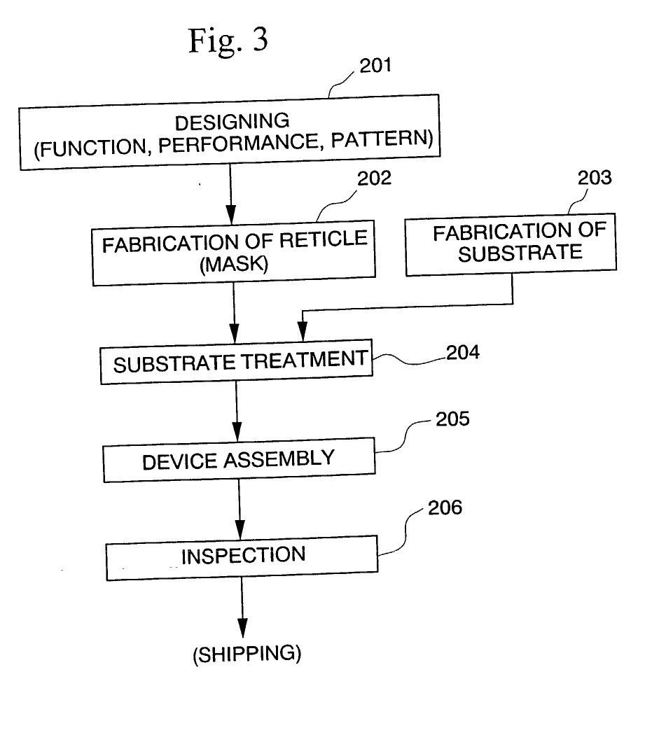

The semiconductor device is produced as shown in FIG. 3 through step 201 where the function and performance of the device are designed, step 202 where the reticle (mask) is fabricated according to the design, step 203 where the substrate (wafer, glass plate) of the device is fabricated, substrate treatment step 204 where the substrate is exposed by the exposure apparatus of the embodiment described above to form the mask pattern, device assembling step 205 (including the dicing process, bonding process and packaging process), inspection step 206, etc.

What is claimed is:

1. A process for forming a latent image, which comprises irradiating a master plate having a pattern with exposure light and irradiating a substrate coated with a resist with the exposure light transmitted through said master plate or reflected on said master plate via a projection optical system, thereby forming the image of the pattern on the substrate, wherein
the image of said pattern is formed on said substrate by making use of a change in color of a predetermined substance, included in said resist, that changes the color thereof according to the irradiation with said exposure light.

2. A process for forming a latent image according to claim 1, wherein said resist includes a specific substance that produces an acidic or basic substance when irradiated with the light; and
said predetermined substance changes the color thereof in reaction to the acidic or basic-substance produced by the specific substance.

3. A process for forming a latent image according to claim 1, wherein said resist is a chemical sensitization type resist that includes said predetermined substance added thereto.

4. A process for forming a latent image, which comprises irradiating a master plate having a pattern with exposure light and irradiating a substrate coated with a resist with the exposure light transmitted through said master plate or reflected on said master plate via a projection optical system, thereby forming the image of said pattern on said substrate, wherein
said substrate is irradiated with said exposure light of a wavelength that changes the thickness of said resist film by at least 3%, thereby forming the image of said pattern on said substrate.

5. A process for detecting a latent image, which comprises irradiating said substrate having the latent image of said pattern being formed thereon with detection light of a wavelength different from that of said exposure light, using the process for forming a latent image of claim 1, and
detecting light generated from the latent image when irradiated with the detection light, thereby detecting said latent image.

6. A process for detecting a latent image, which comprises irradiating said substrate having the latent image of said pattern being formed thereon with detection light of a wavelength different from that of said exposure light, using the process for forming a latent image of claim 4, and
detecting light generated from the latent image when irradiated with said detection light, thereby detecting said latent image.

7. An exposure process, which comprises determining positional information of said latent image detected using the process for detecting a latent image of claim 5, and
carrying out alignment of said substrate or measurement of the alignment accuracy according to the positional information of said latent image.

8. An exposure process, which comprises determining positional information of said latent image detected using the process for detecting a latent image of claim 6, and
carrying out alignment of said substrate or measurement of the alignment accuracy according to the positional information of said latent image.

9. A device produced by using the exposure process of claim 7.

10. A device produced by using the exposure process of claim 8.

11. An exposure apparatus for forming an image of a pattern on a substrate by irradiating a master plate having the pattern with exposure light and irradiating the substrate coated with the resist with the exposure light transmitted through the master plate or reflected on the master plate via a projection optical system, comprising:
a detector, which includes a photoelectric element, and which detects a latent image, which has been formed on said substrate by making use of a change in the color of a predetermined substance, that changes color when irradiated with said exposure light and is included in a resist, by irradiating detection light of a wavelength different from that of the exposure light; and
an alignment device, which is electrically connected to said detector, and which carries out alignment of said substrate according to the result of detection by said detector.

12. An exposure apparatus according to claim 11, wherein said resist includes a specific substance that produces an acidic or basic substance when irradiated with the light; and
said predetermined substance changes color in reaction to the acidic or basic substance produced by the specific substance.

13. An exposure apparatus according to claim 11, wherein said resist is a chemical sensitization type resist that includes said predetermined substance added thereto.

14. An exposure apparatus for forming an image of a pattern on a substrate by irradiating a master plate having the pattern with light and irradiating the substrate coated with the resist with the light transmitted through said master plate or reflected on said master plate via a projection optical system, comprising:
a detector, which includes a photoelectric element, and which detects a latent image, which is formed on said substrate by irradiating said substrate with exposure light of a wavelength that changes the thickness of said resist by at least 3%, by using detection light of a wavelength different from that of said exposure light; and
an alignment device, which is electrically connected to said detector, and which carries out alignment of said substrate according to the result of detection by said detector.

15. A resist comprising:
a specific substance that produces an acidic or basic substance when irradiated with the light of a predetermined wavelength; and
a predetermined substance that changes color in reaction to the acidic or basic substance produced by said specific substance.

16. A resist according to claim 15, wherein said resist is a chemical sensitization type resist that includes said predetermined substance added thereto.

17. A resist that reduces its thickness by at least 3% when irradiated with light having a predetermined wavelength.

18. A resist according to claim 17, wherein said is a chemical sensitization type resist.

19. A substrate that is coated with said resist of claim 15 and has a latent image formed through a change in the resist in accordance to the irradiation with the light of said predetermined wavelength.

20. A substrate that is coated with said resist of claim 17 and has a latent image formed through a change in the resist in accordance to the irradiation with the light of said predetermined wavelength.
